(19) United States
(12) Patent Application Publication
(10) Pub. No.: US 2005/0153507 A1
(43) Pub. Date: Jul. 14, 2005

(54) Fabrication method for a trench capacitor with an insulation collar

(75) Inventors: Thomas Hecht, Dresden (DE); Till Schlosser, Dresden (DE); Michael Sesterhenn, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/013,921

(22) Filed: Dec. 17, 2004

(30) Foreign Application Priority Data
Dec. 18, 2003 (DE) 103 59 580.5

(51) Int. Cl. H01L 21/8242; H01L 21/76

(52) U.S. Cl. 438/243

(57) ABSTRACT

The present invention provides a fabrication method for a trench capacitor with an insulation collar in a substrate, which is electrically connected to the substrate on one side via a buried contact. After forming and sinking an electrically conductive filling, an insulation collar and, if appropriate, a buried contact that is connected on all sides, the following are effected: providing at least one liner layer in the trench; filling the trench with a filling made of an auxiliary material, which filling is encapsulated by the at least one liner layer in the trench; providing a mask on the filling for defining the structure of the buried contact, the mask having no projections into the trench; removing a part of the filling using the mask; removing an underlying part of the at least one liner layer for uncovering a corresponding part of the insulation collar.

### CLAIM FOR PRIORITY

This application claims the benefit of priority to German Application No. 103 59 580.5, which was filed in the German language on Dec. 18, 2003; the contents of which are hereby incorporated by reference.

### TECHNICAL FIELD OF THE INVENTION

The present invention relates to a fabrication method for a trench capacitor with an insulation collar, which is electrically connected to a substrate on one side via a buried contact, in particular for a semiconductor memory cell.

### BACKGROUND OF THE INVENTION

Although applicable in principle to any desired integrated circuits, the present invention and also the problem area on which it is based are explained with regard to integrated memory circuits in silicon technology.

The abovementioned method and further similar known methods have problems if the procedure involves producing a deeply situated buried contact in a trench with a very high aspect ratio (typically >3), such as occurs for example in the case of DRAMs with a design rule of less than 70 nm.

### SUMMARY OF THE INVENTION

The present invention discloses a simple and reliable fabrication method a trench capacitor that is connected on one side with a high aspect ratio.

One advantage of the method according to the invention is that it enables a precise definition of the connection zone in the case of the respective buried contact of the trench capacitor even with a high aspect ratio.

A further advantage of the present invention is that the self-aligned structure can be constructed near the surface even in the case of concepts having a high aspect ratio on account of the filling made of the auxiliary material. The self-aligned mask has no overhangs from the surrounding periphery of the trench into the trench and can thus be transferred very easily into the depth.

Projections of the mask into the trench, after an unavoidable but undesired dose deposition at the mask edge during the implantation, would prevent a wall-flush transfer of the mask into the trench by shading. For this reason, the non-overhanging masks are constructed with a plug in the center. A special sequence for producing such overhangless masks is expedient whenever the implantation reduces the etching rate at the implanted locations, as is the case e.g. with boron in silicon. The Al₂O₃ liner variant, in which implantation is effected using argon, has the advantage that the implantation increases the etching rate in the implanted region and, consequently, a non-overhanging masks are automatically fabricated by the selective etching.

In one embodiment of the present invention, there is transfer of a structure defined in the vicinity of the substrate surface by means of a non-overhanging masking into the depth at the location of the buried contact by means of auxiliary material that can be removed unproblematically.

In accordance with one preferred embodiment, providing the mask on the filling includes:
sinking the filling into the trench;
providing a further liner layer in the trench;
carrying out an oblique implantation into the liner layer for the purpose of defining the mask; and
selectively etching the further liner layer for the purpose of removing the non-implanted or implanted region.

In accordance with a further preferred embodiment, the further liner layer is a silicon liner layer and, after the removal of the implanted or non-implanted region by the selective etching, an oxidation of the remaining region of the silicon liner layer is carried out, the oxidized region that has not been selectively etched forming the mask.

In accordance with a further preferred embodiment, the further liner layer is an Al₂O₃ liner layer and, after the removal of the implanted or non-implanted region by the selective etching, the remaining region forms the mask.

In accordance with a further preferred embodiment, the auxiliary material of the filling is silicon or borophosphosilicate glass.

In accordance with a further preferred embodiment, providing the further liner layer in the trench includes:
depositing the silicon liner layer over the hard mask and the sunk filling;
providing a silicon oxide filling that is planar with the top side of the silicon liner layer;
pulling back the silicon liner layer to below the top side of the hard mask; and
removing the silicon oxide filling.

In accordance with a further preferred embodiment, the mask is removed after removal of a part of the filling using the mask by carrying out a further implantation and afterward a further selective etching.

### BRIEF DESCRIPTION OF THE DRAWINGS

Exemplary embodiments of the invention are illustrated in the drawings and explained in more detail in the description below.

FIGS. 1A-O show successive method stages of a fabrication method as first embodiment of the present invention.

FIGS. 2A-L show successive method stages of a fabrication method as second embodiment of the present invention.

FIGS. 3A-D show successive method stages of a fabrication method as third embodiment of the present invention.

FIGS. 4A-E show successive method stages of a fabrication method as fourth embodiment of the present invention.

In the figures, identical reference symbols designate identical or functionally identical constituent parts.

### DETAILED DESCRIPTION OF THE INVENTION

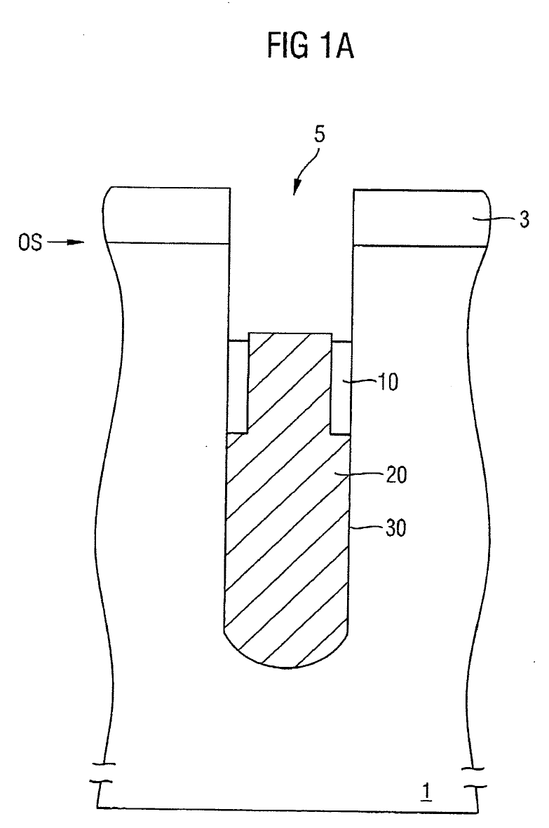

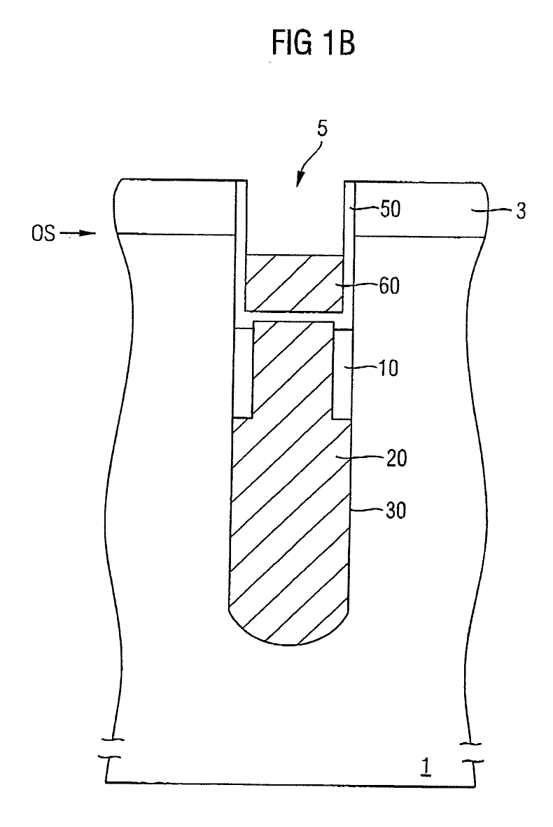

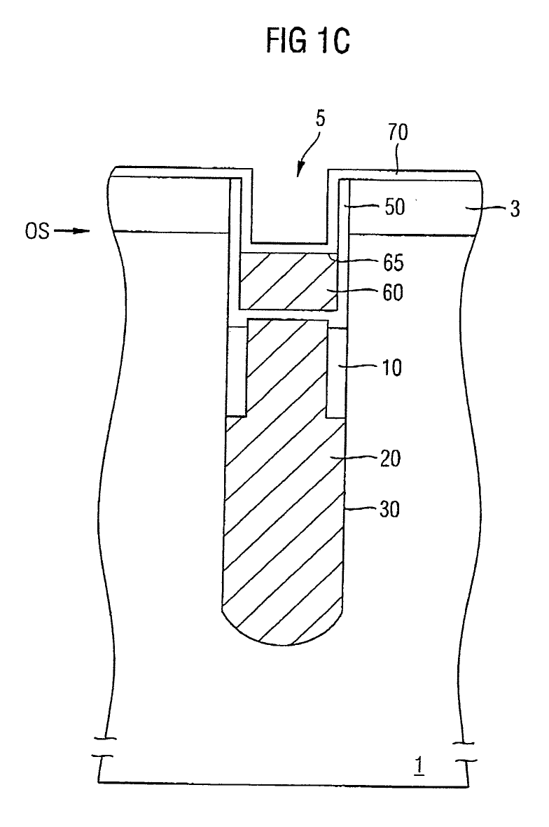

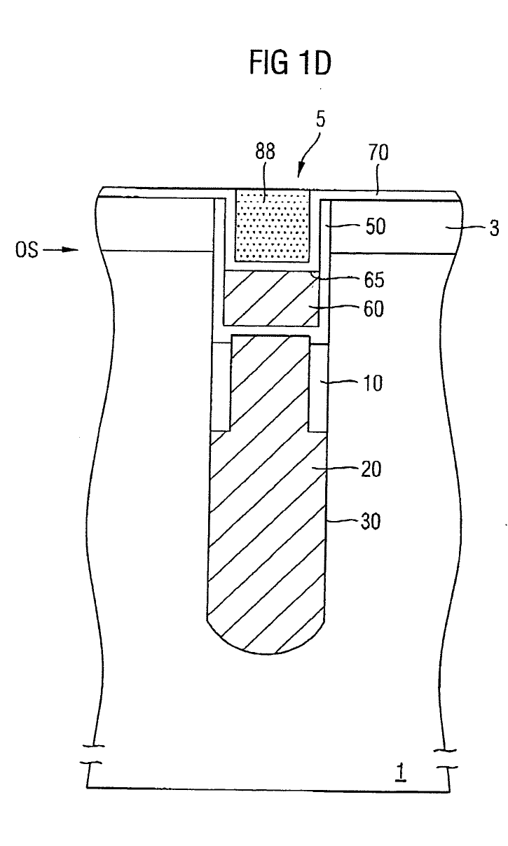

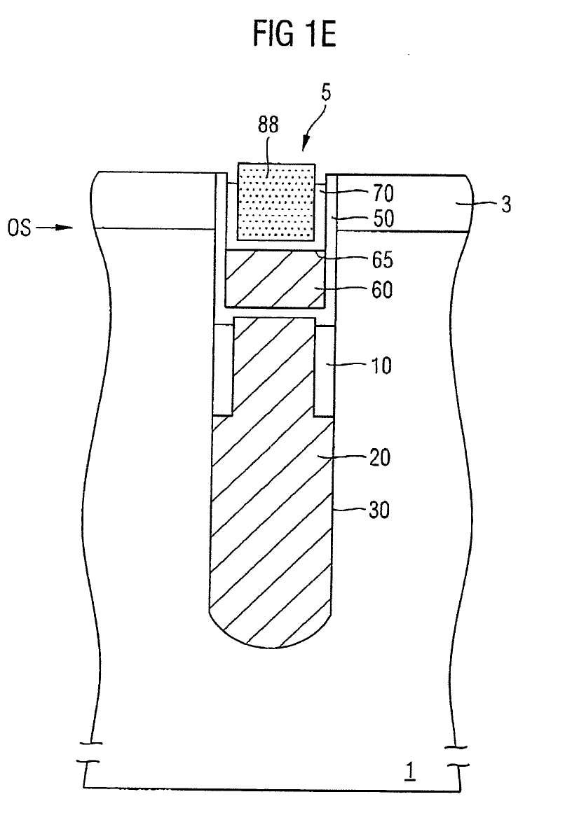

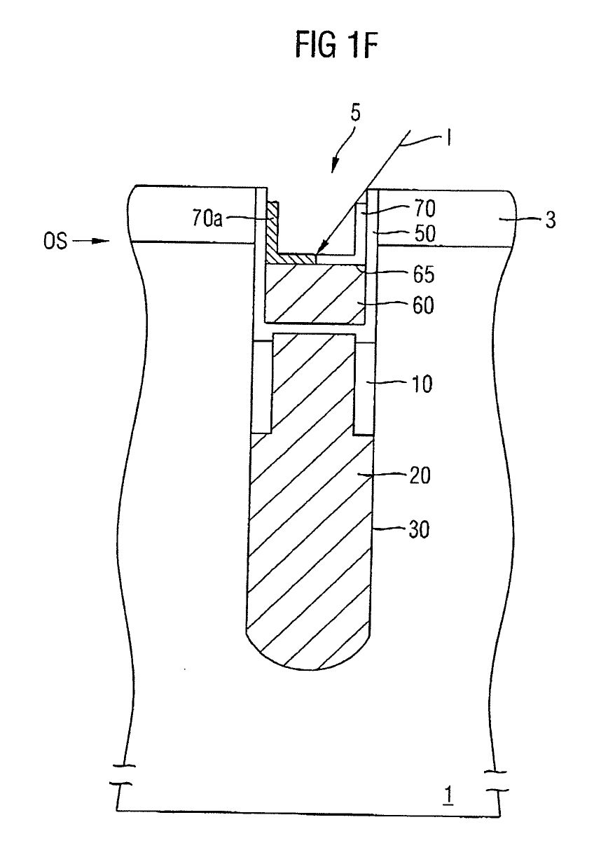

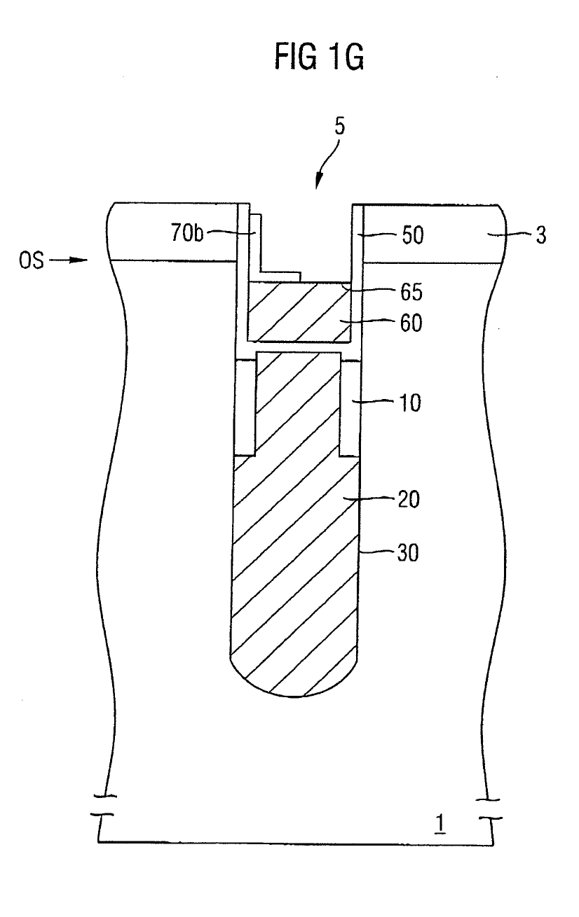

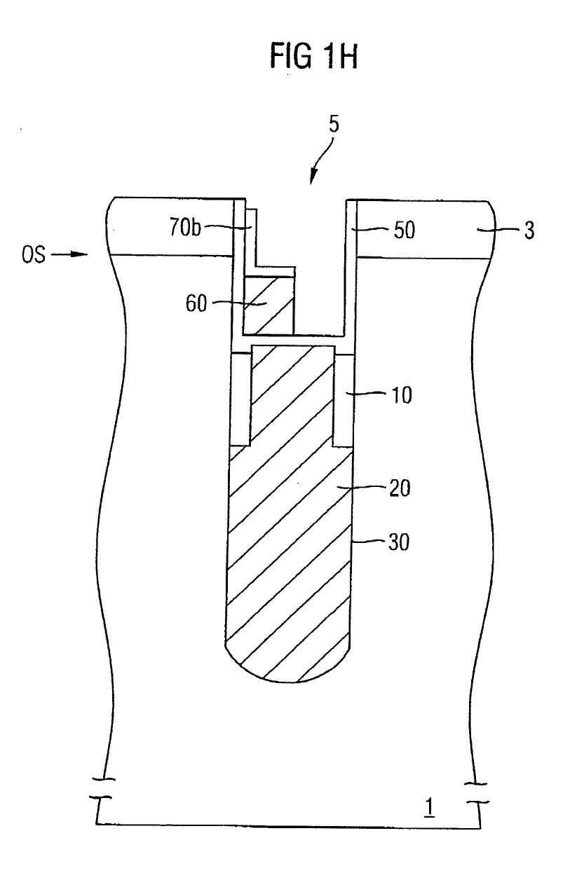

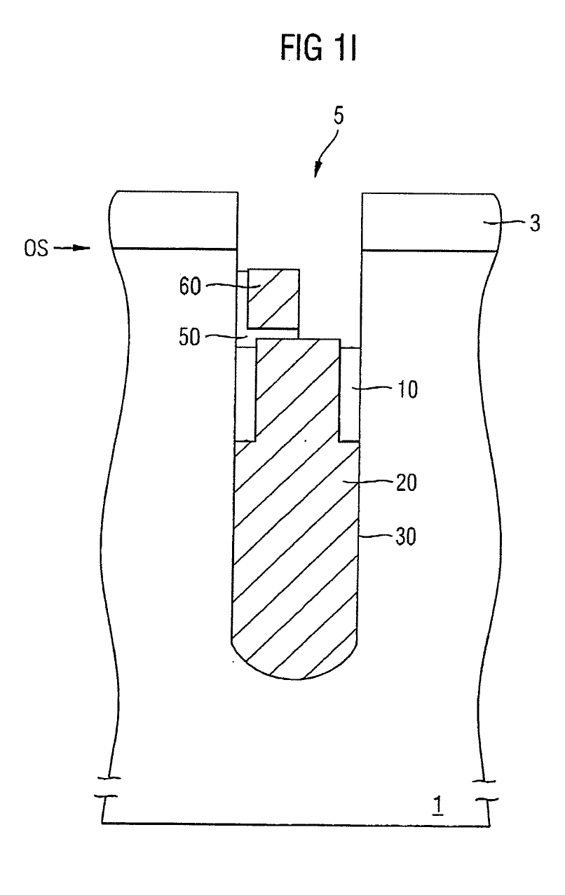

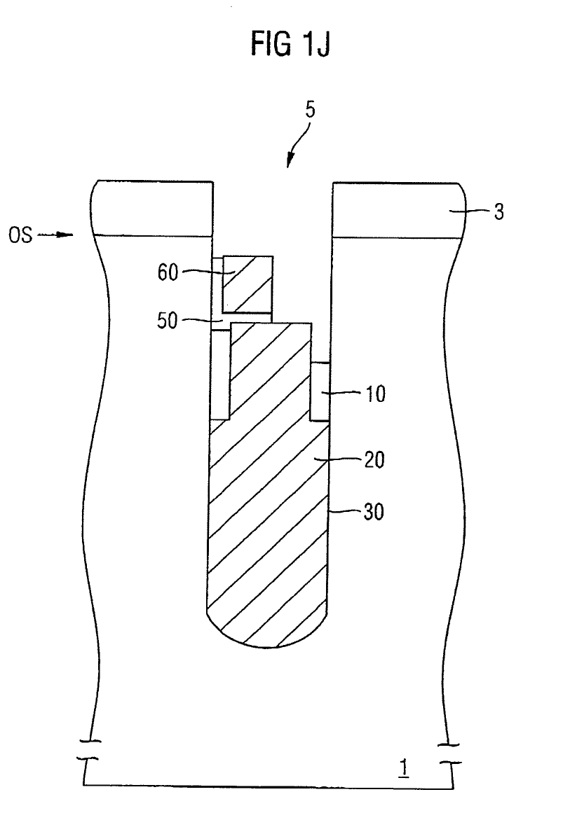

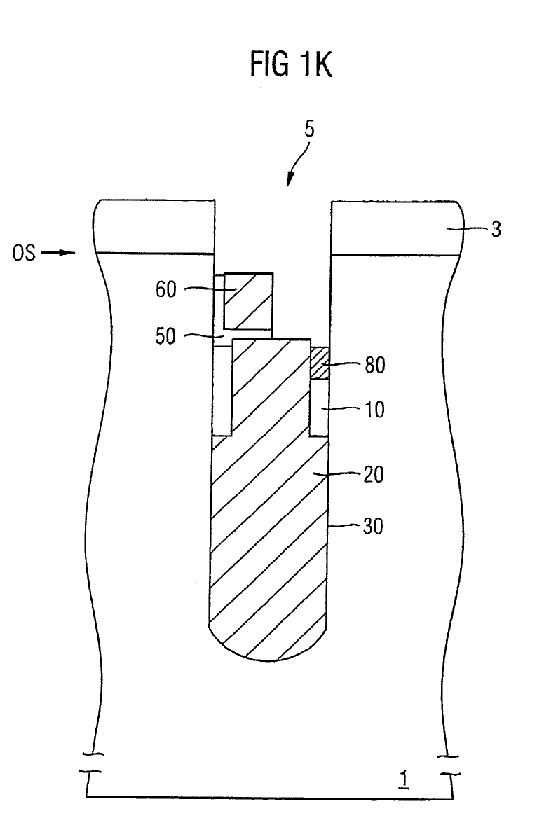

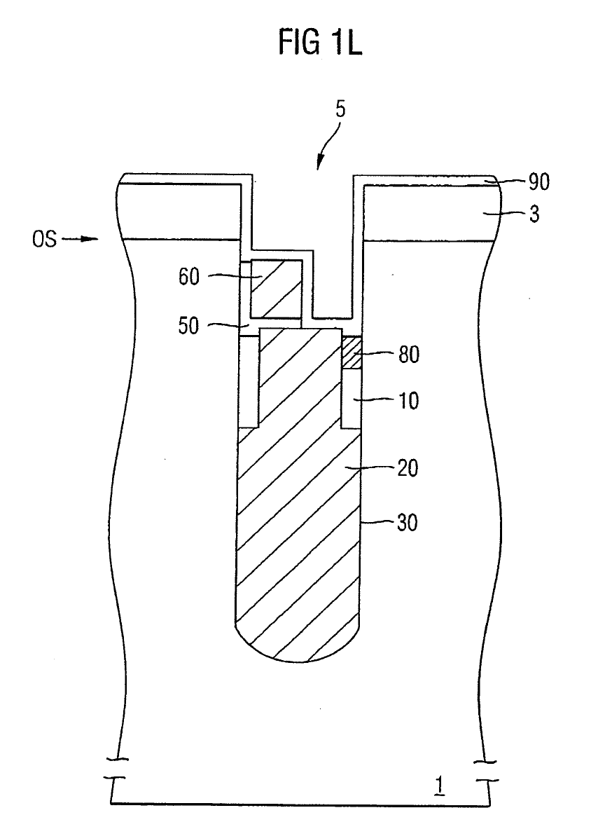

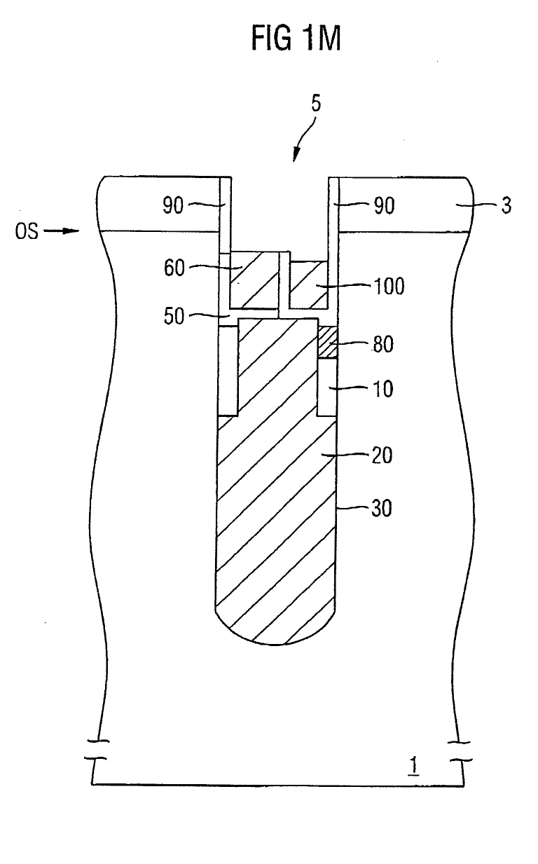

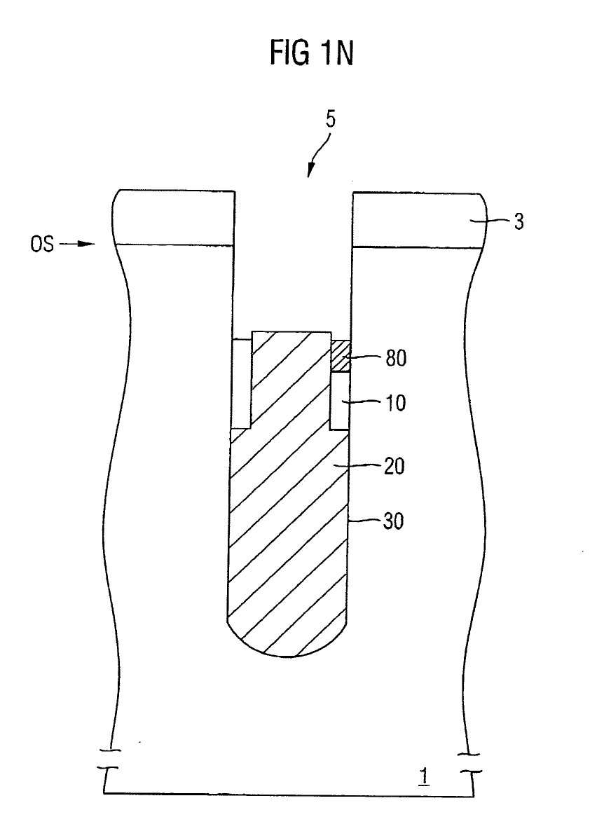

FIGS. 1A-O illustrate successive method stages of a fabrication method as first embodiment of the present invention.

In FIG. 1A, reference symbol 1 designates a silicon semiconductor substrate, in which a trench 5 has been provided by means of a hard mask 3. A thin capacitor dielectric 30 is situated on the trench walls in the lower region, said capacitor dielectric together with the substrate 1 and a conductive filling 20 preferably made of polysilicon, which filling is provided in the interior of the trench 5, forming a capacitor. An insulation collar 10 preferably made of silicon oxide is provided in the central and upper trench regions. Both the conductive filling 20 and the insulation collar 10 are sunk relative to the top side OS of the semiconductor substrate 1.

In a subsequent process step illustrated in FIG. 1B, firstly an oxinitride liner layer 50 is deposited over the resulting structure. Then the trench 5 is filled with a further filling 60 preferably made of amorphous or polycrystalline silicon and the filling 60 is planarized by means of a chemical mechanical polishing step and then etched back to below the top side OS of the semiconductor substrate 1. In this case, the oxinitride liner layer 50 is also removed from the surface of the hard mask 3. The filling 60 serves for structure transfer in the later course of the process, as described below.

Continuing with reference to FIG. 1C, the surface of the resulting structure is then either nitrided to a great extent or a very thin silicon nitride liner layer 65 is deposited over the resulting structure. This nitriding serves as a diffusion barrier during the subsequent oxidation of the hard mask 70 with respect to the filling 60. An amorphous or polycrystalline silicon liner layer 70 is then preferably provided over the silicon nitride liner layer 65.

Continuing with reference to FIG. 1D, the trench 5 is then preferably closed with a silicon oxide filling 88, which is polished back as far as the top side of the amorphous silicon liner layer 70.

Continuing with reference to FIG. 1E, the amorphous or polycrystalline silicon liner layer 70 is then pulled back to below the upper edge of the hard mask 3, so that it is completely removed from the surface of the hard mask 3.

As illustrated in FIG. 1F, the preferably silicon oxide filling 88 is then removed from the trench 5 and afterward at least one oblique and possibly rotated implantation step I is carried out, during which preferably boron ions are implanted into a partial region 70a of the amorphous or polycrystalline silicon liner layer 70. In order to cover the partial region 70a, it is necessary to pivot and, if appropriate, to rotate the implantation direction during the implantation step I perpendicular to the plane of the drawing.

As illustrated in FIG. 1G, either the non-implanted region or the implanted region of the amorphous or polycrystalline silicon liner layer 70 is then removed selectively by an etching. This is followed by an oxidation of the remaining region 70a of the amorphous or polycrystalline silicon liner layer 70 for the purpose of forming an oxidized region 70b.

In this case, the nitriding or the thin silicon nitride liner 65 on the surface of the preferably amorphous or polycrystalline silicon filling 60 prevents the wet-chemical etching from penetrating into the filling 60, on the one hand, and the oxidation of the filling 60 during the oxidizing of the region 70b, on the other hand.

Continuing with reference to FIG. 1H, the nitriding or the thin silicon nitride liner 65 is then penetrated and the region left free of the oxidized region 70b is transferred into the preferably amorphous or polycrystalline silicon filling 60 by an etching.

Continuing with reference to FIG. 1I, the oxidized region 70b and the region of the preferably oxinitride liner layer 50 that is uncovered in the trench are then removed by a respective etching.

In the subsequent process step shown in FIG. 1J, by means of a dry etching, the insulation collar 10 is removed in the uncovered region and the window for the later buried contact is thus uncovered. In order to remove the insulation collar 10 from this window without any residues, there follows a wet-chemical cleaning of the etching pit.

As illustrated in FIG. 1K, firstly the surface is then nitrided for the purpose of conditioning the uncovered semiconductor substrate 1, and this is followed by a divot filling and divot etching of a preferably amorphous or polycrystalline polysilicon layer 80, which ultimately electrically connects the conductive filling 20 to the substrate 1 in a half-sided manner and thus forms the buried contact.

The buried connection has actually already been structurally formed at this point in time, but it may be advantageous also to remove the remaining liner layer 50 and preferably amorphous or polycrystalline polysilicon filling 60 in the trench. For this purpose, in accordance with FIG. 1L, firstly a further preferably oxinitride liner layer 90 is provided over the resulting structure.

Afterward, in accordance with FIG. 1M, the upper region of the trench 5 is preferably filled with a further amorphous or polycrystalline silicon filling 100 and the latter is sunk, after which the oxinitride liner layer 90 that is uncovered on the top side is preferably opened by a dry etching (spacer etching). In the course of sinking the polysilicon filling 100, it is expedient for the top side thereof to be sunk deeper than the top side of the polysilicon filling 60, in order that the oxinitride liner 90 can be removed on the top side of the first polysilicon filling 60 by means of the simple spacer etching. The purpose of the oxinitride liner layers 50, 90 becomes clear particularly in connection with FIG. 1M since the semiconductor substrate 1 and the filling 20 would be etched without these liners.

In accordance with FIG. 1N, the uncovered amorphous or polycrystalline silicon fillings 60 and 100 are then removed by an etching and the remaining oxinitride liner layer 50 and 90 is likewise stripped.

After the process state in accordance with FIG. 1N, in which all auxiliary materials have been removed from the trench 5, in accordance with FIG. 10 the trench is preferably closed by means of a silicon oxide filling 110 up to the top side of the semiconductor substrate.

Particular advantages of this first embodiment are that it is possible to form the window for the buried connection in the depth in a self-aligned manner, and the size of the window does not depend on the tolerances of two etching-back processes. The buried connection is created additively, and the resistance of the buried contact can be set in minimal fashion on account of the maximum cross section. Processes employed for this self-aligned construction of the buried contact are fundamental standard processes.

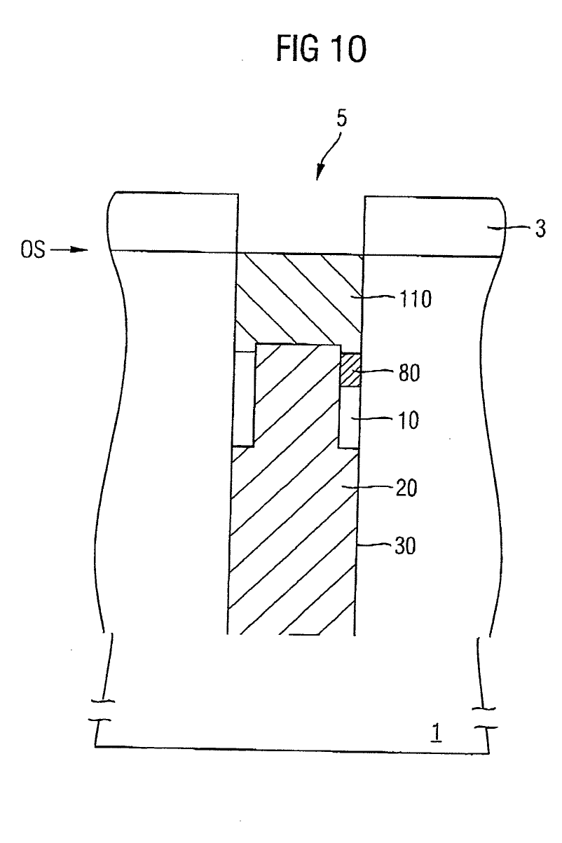

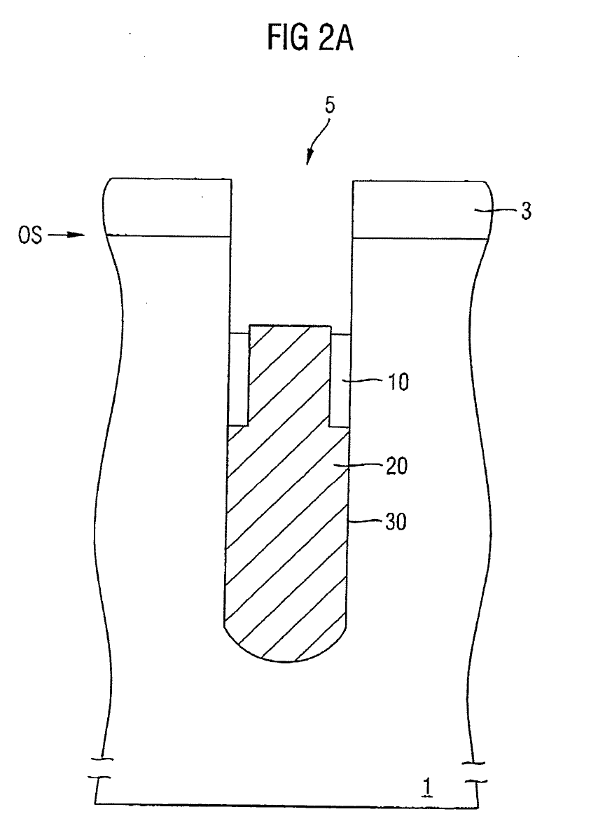

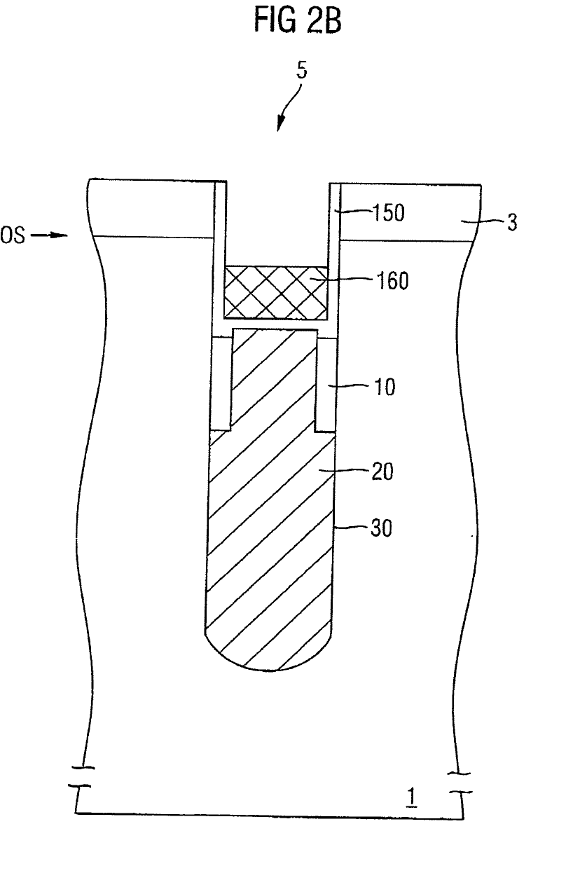

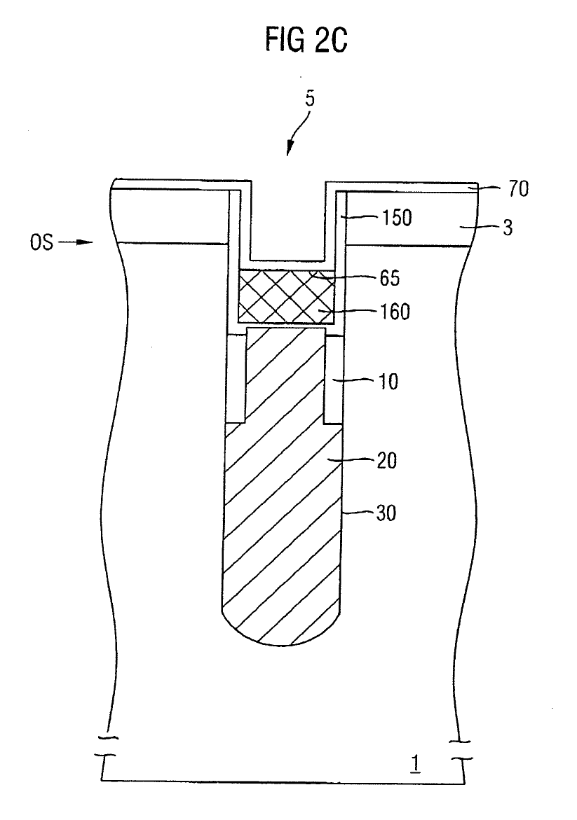

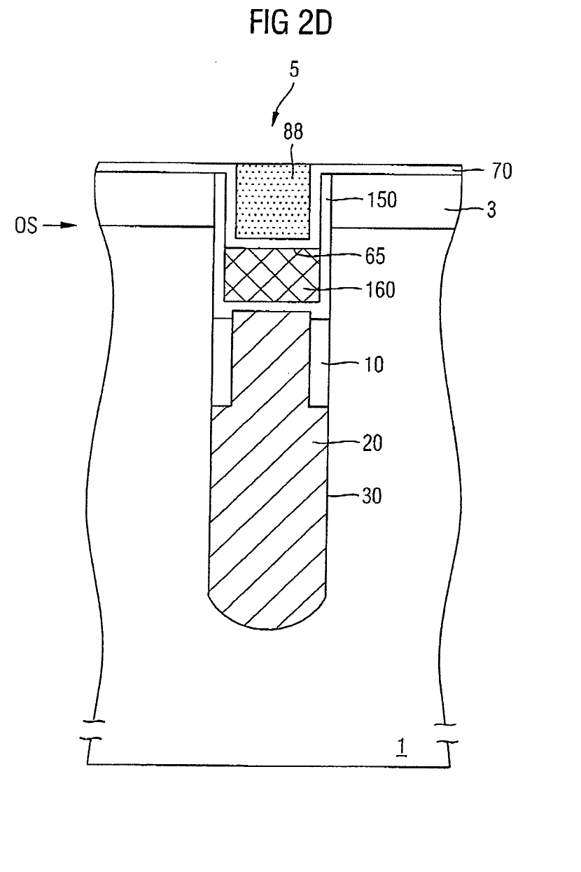

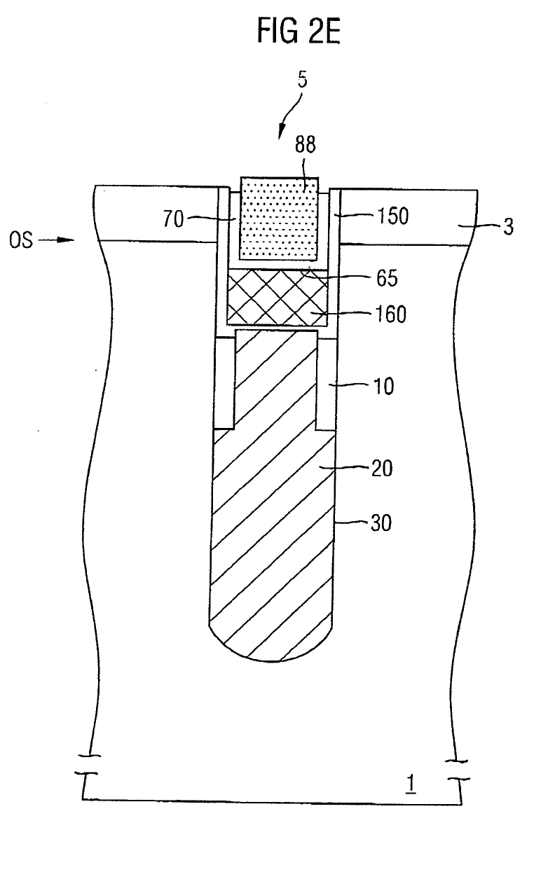

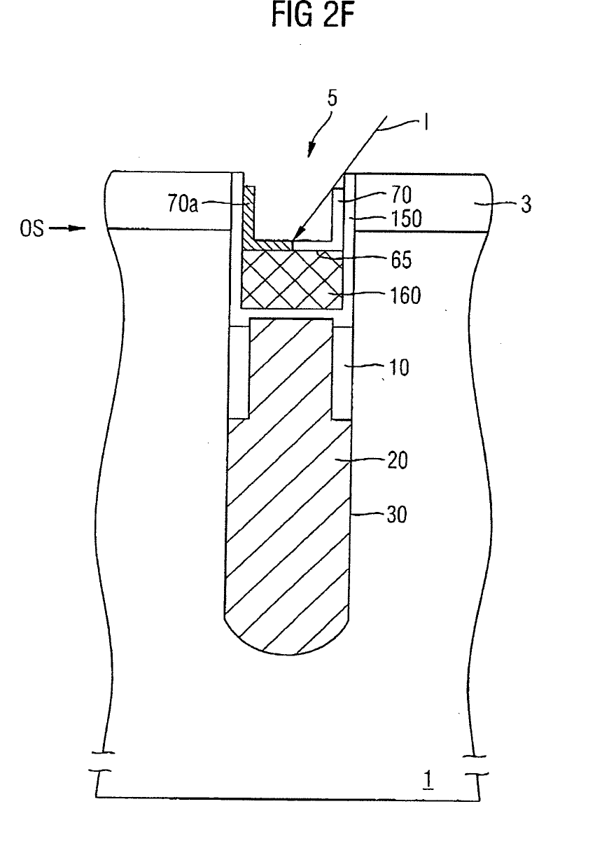

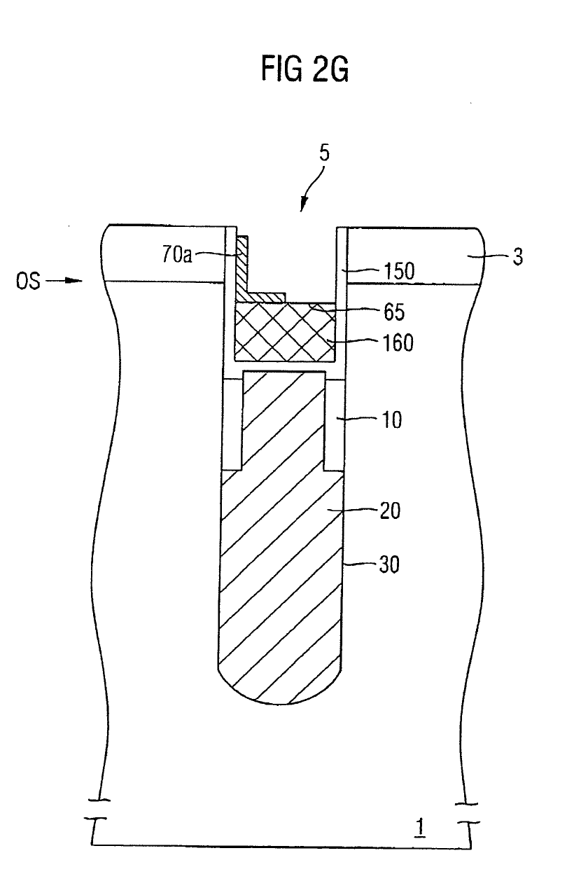

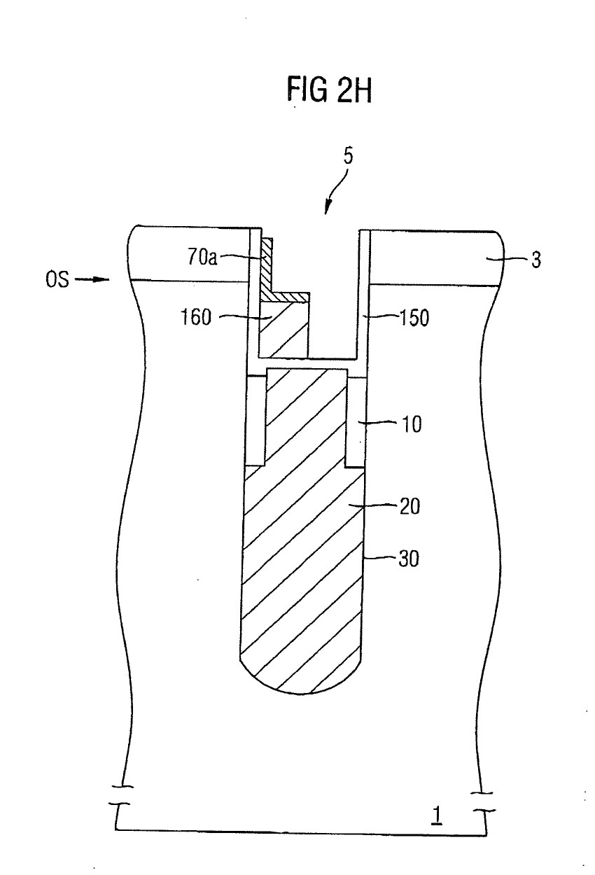

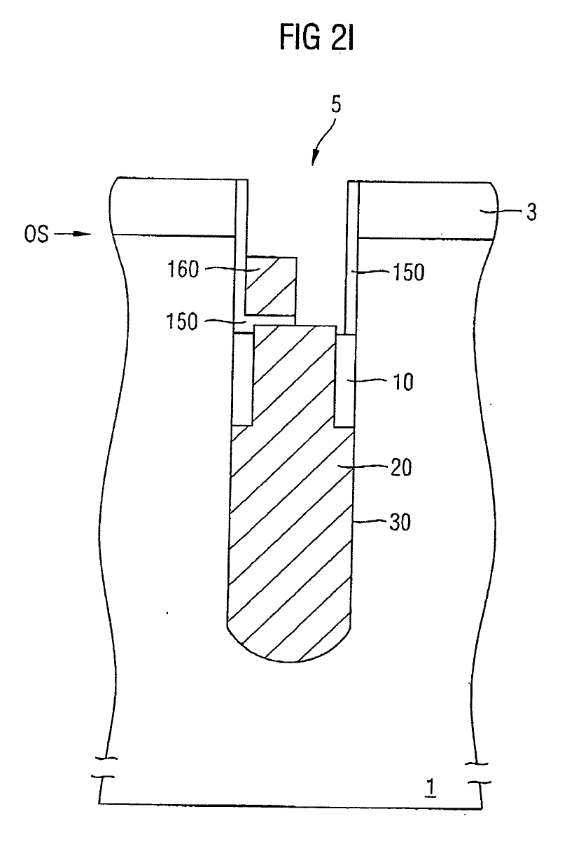

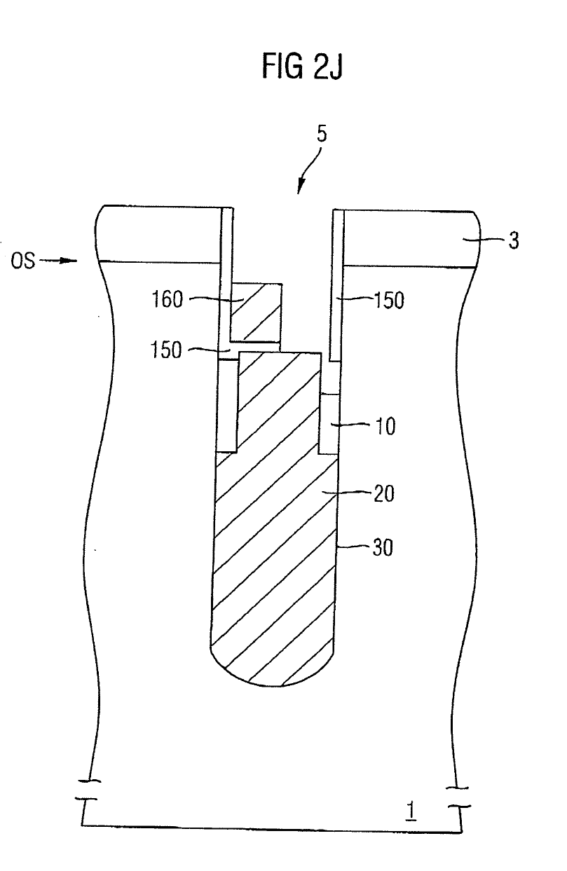

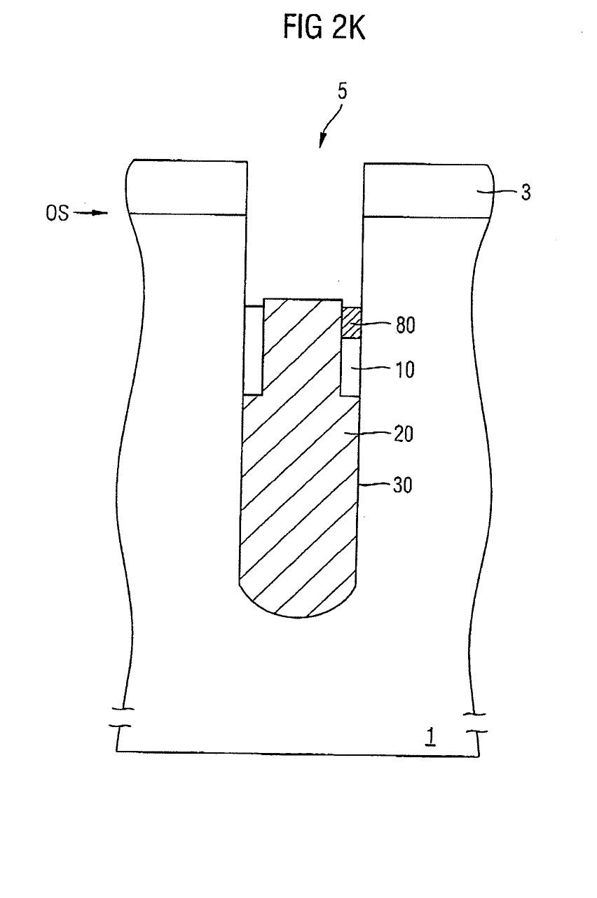

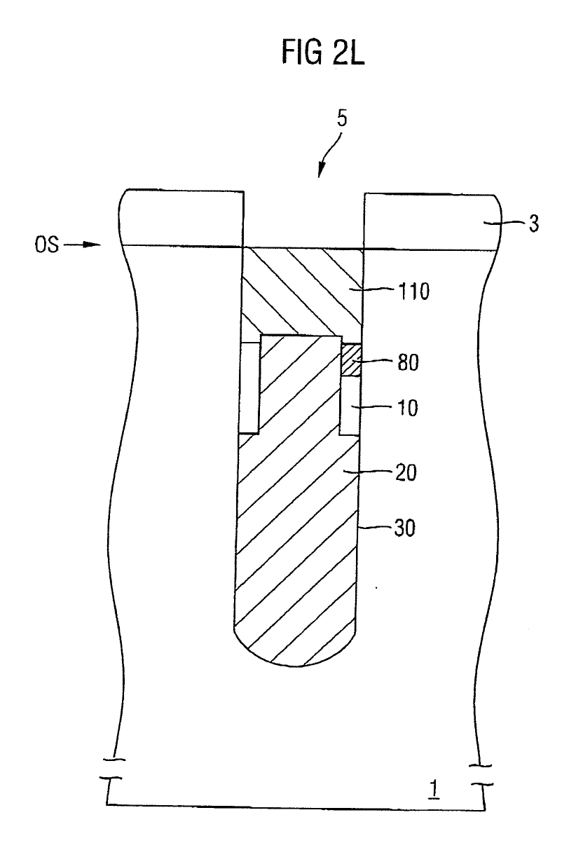

FIGS. 2A-L are diagrammatic illustrations of successive method stages of a fabrication method as second embodiment of the present invention.

The process state shown in FIG. 2A corresponds to the process state shown in FIG. 1A.

In accordance with FIG. 2B, a silicon nitride liner layer 150 and a filling made of BPSG (borophosphosilicate glass) are deposited over the structure. An annealing process for the BPSG filling 160 is followed by a chemical mechanical polishing-back of the BPSG filling 160 and the silicon nitride liner layer 150 and an etching-back of the BPSG filling 160 to below the top side OS of the semiconductor substrate 1.

Continuing with reference to FIG. 2C, a very thin silicon nitride liner layer 65 is then deposited over the resulting structure. This nitriding serves as a diffusion barrier in order that the boron does not outdiffuse from the BPSG during the subsequent high-temperature steps.

In accordance with FIG. 2C, a silicon liner layer 70 is furthermore deposited over the resulting structure and a silicon oxide filling 88 is provided thereon. After the polishing-back of the silicon oxide filling 88, which is shown in FIG. 2D, the silicon liner layer 70 is selectively etched back to below the surface of the hard mask 3 in accordance with FIG. 2E.

As illustrated in FIG. 2F, at least one oblique and possibly rotated implantation I of BF₂ ions is then effected, which creates an implanted region 70a of the silicon liner layer 70, whereas the remainder thereof remains shaded from the implantation.

By means of a selective etching, it is then possible, in accordance with FIG. 2G, to remove the non-implanted region of the silicon liner layer 70, while the implanted region 70a of the silicon liner layer 70 remains as a mask on the filling 160 made of BPSG.

In accordance with FIG. 2H, the BPSG filling 160 is then etched selectively using the implanted region 70a as a mask. In the process state shown in FIG. 2I, the mask in the form of the implanted region 70a has been selectively removed by an etching and the uncovered silicon nitride liner layer 150 has been removed by a dry etching in regions above the conductive filling 20 and above the insulation collar 10. In the subsequent process illustrated in FIG. 2J, the insulation collar 10 is etched back in the uncovered region.

Afterward, as shown in FIG. 2K, the remainder of the BPSG filling 160 and of the silicon nitride liner layer 150 is removed by corresponding etching steps, whereupon a nitriding takes place and the buried contact 80 is formed between the conductive filling 20 and the semiconductor substrate by means of a divot filling and divot etching-back of a silicon layer. Finally, the trench is closed by means of a silicon oxide filling 110.

The first and second embodiments above employed a so-called additive method in order to remove a part of the insulation collar 10 and to replace it by the buried contact 80. By contrast, the third and fourth embodiments described below employ a so-called subtractive method in order to remove in regions a buried contact 80 that is connected on all sides and to replace the latter by an insulation region.

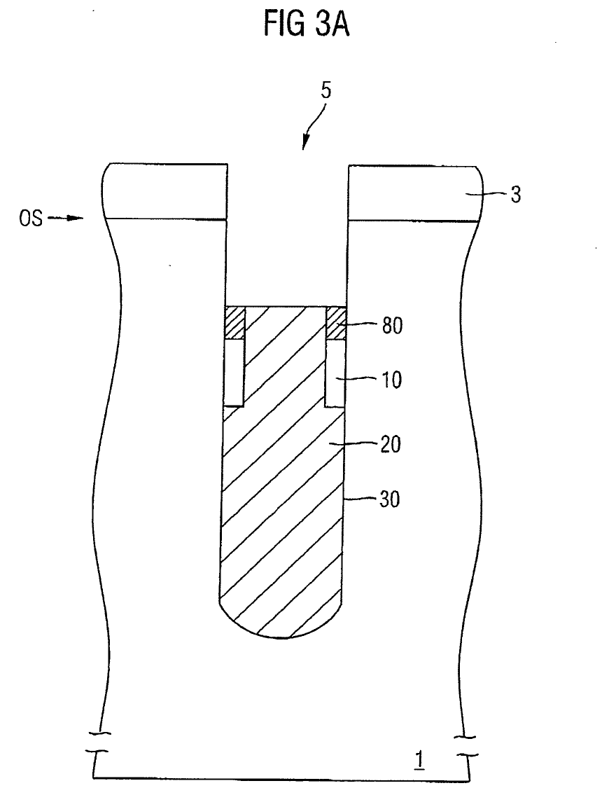

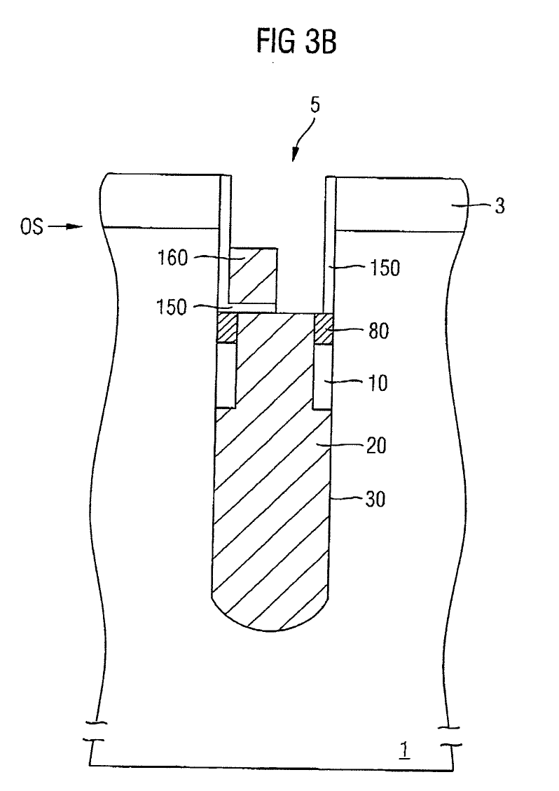

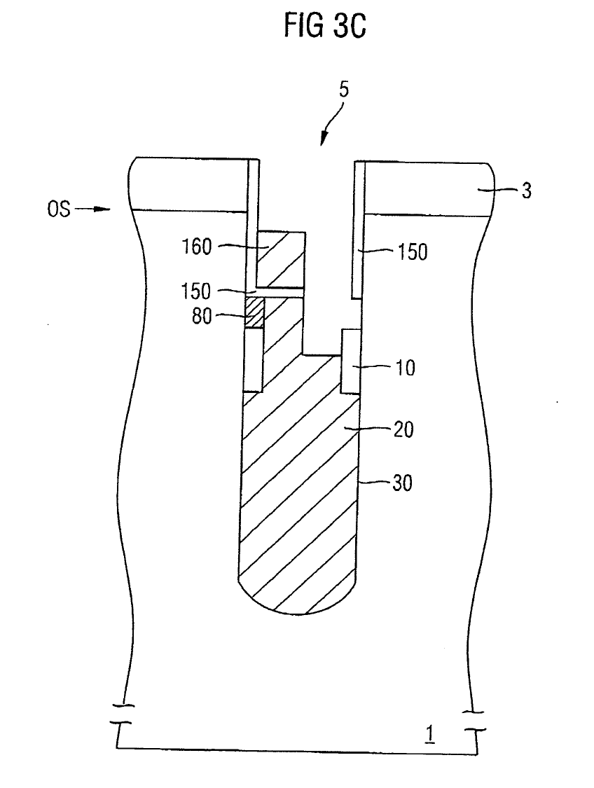

FIGS. 3A-D are diagrammatic illustrations of successive method stages of a fabrication method as third embodiment of the present invention.

In accordance with the process state shown in FIG. 3A, the insulation collar 10 has firstly been lowered relative to the top side of the conductive filling 20, then firstly the surface has been nitrided for the purpose of conditioning the uncovered semiconductor substrate 1, and a peripheral buried contact 80 that is connected on all sides has thereupon been formed by means of a divot filling and divot etching-back of silicon.

The process steps that follow FIG. 3A in order to attain the process state according to FIG. 3B correspond to the process steps in accordance with FIGS. 2B to 2I which have already been explained above in connection with the second embodiment.

In accordance with FIG. 3C, the conductive filling 20 and a part of the buried contact 80 are then etched using the patterned filling made of BPSG 160 as a mask in order thus to remove the buried contact 80 from the later insulation region.

Continuing with reference to FIG. 3D, the following are then effected: a divot filling and divot etching of a silicon oxide filling 109 and also a subsequent deposition and etching-back of a further silicon oxide filling 110.

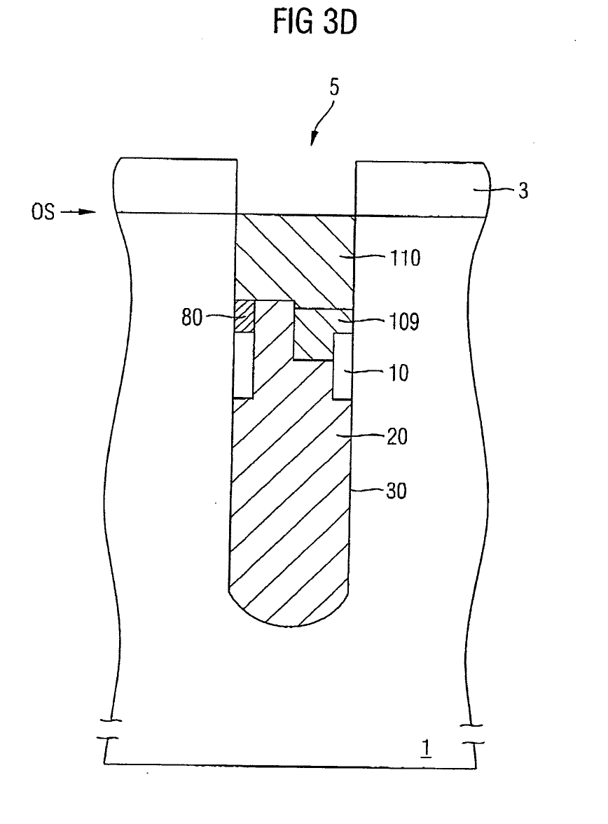

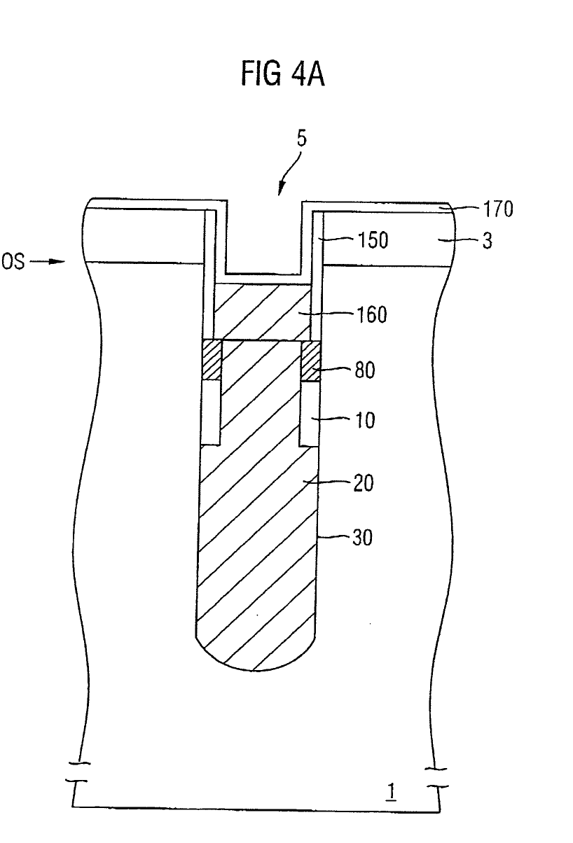

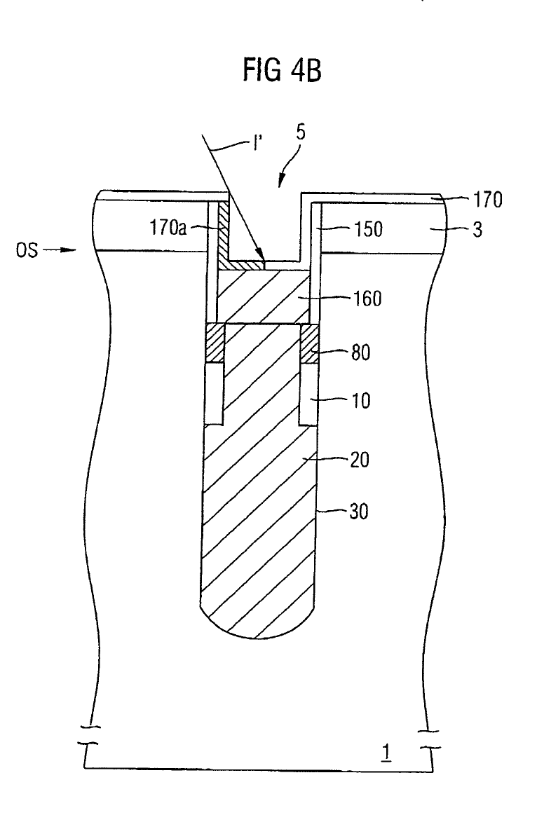

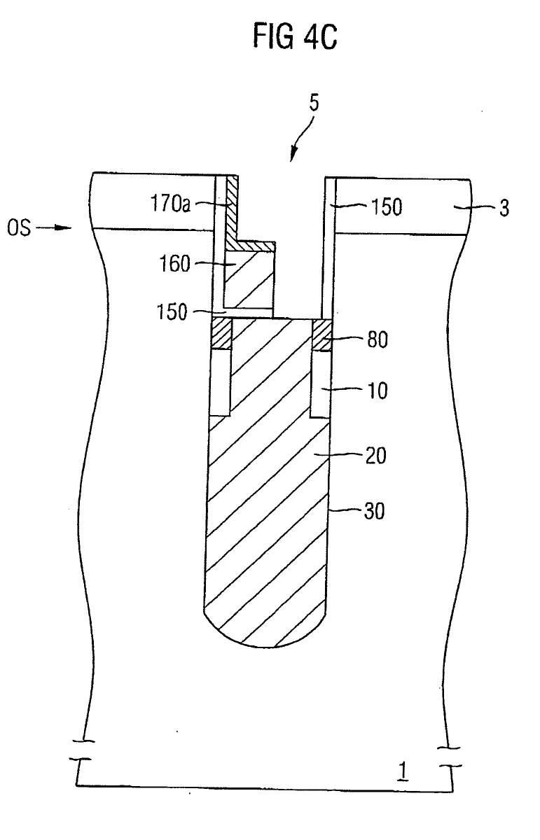

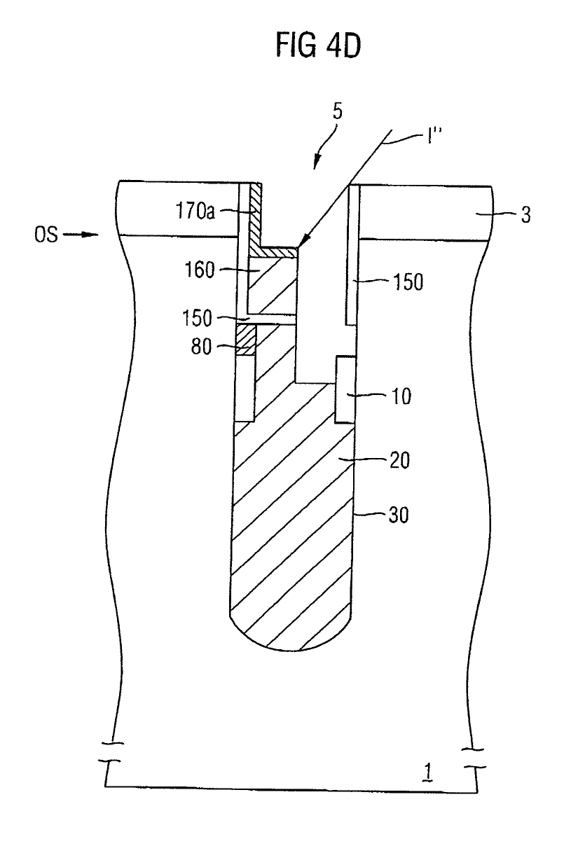

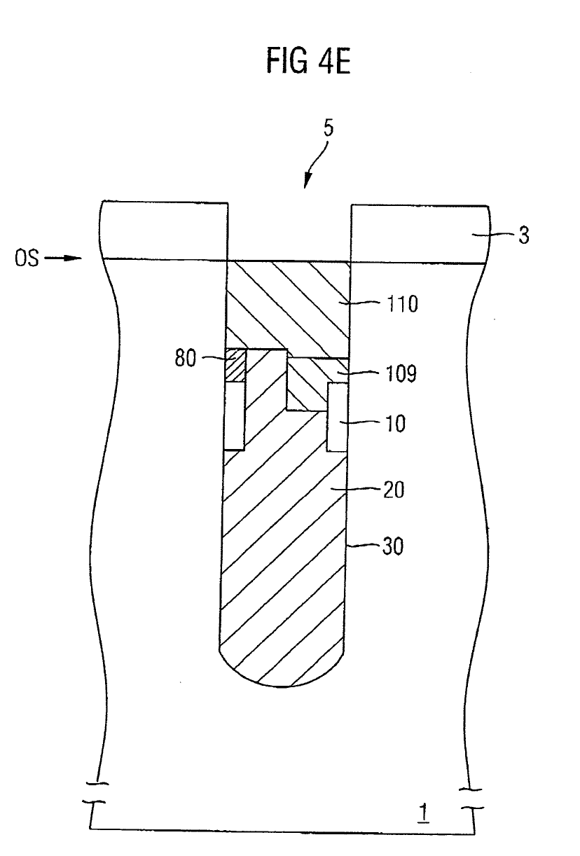

FIGS. 4A-E are diagrammatic illustrations of successive method stages of a fabrication method as fourth embodiment of the present invention.

The process state shown in FIG. 4A corresponds to the process state in accordance with FIG. 2C with the exception of the fact that, instead of a silicon liner layer 70, an Al₂O₃ liner layer 170 of the top side of the structure is provided, and that the insulation collar 10 has firstly been lowered relative to the top side of the conductive filling 20 and a peripheral buried contact 80 that is connected on all sides has thereupon been formed by means of a divot filling and divot etching-back of silicon.

An oblique implantation I′ with argon ions further ensues, with reference to FIG. 4B, during which a region 170a of the Al₂O₃ liner layer 170 remains shaded. In a subsequent etching illustrated in FIG. 4C, firstly the implanted region of the Al₂O₃ liner layer 170 is removed, whereupon the non-implanted region 170a remains as a mask.

By means of this mask, in accordance with FIG. 4C, firstly a part of the BPSG filling 160 is removed and then the silicon nitride liner layer 150 is opened.

Afterward, in accordance with FIG. 4D, as in the case of the third embodiment, a silicon etching is effected for the purpose of removing a part of the conductive filling 20 and the buried contact 80. In a further process step that is likewise shown in FIG. 4D, a further implantation I″ with argon ions is effected in order to make the region 170a of the Al₂O₃ liner layer 170 etchable. This region is subsequently removed by a corresponding etching, and so is the remainder of the BPSG filling 160 and of the silicon nitride liner layer 150.

In accordance with FIG. 4E, as in the case of the third embodiment, the following are then effected: a divot filling and divot etching of a silicon oxide filling 190 and also the deposition and etching-back of a further silicon oxide filling 110.

Although the present invention has been described above on the basis of four preferred exemplary embodiments, it is not restricted thereto, but rather can be modified in diverse ways.

In particular, the selection of the filling and layer materials is only by way of example and can be varied in many different ways.

List of Reference Symbols

1 Si semiconductor substrate
OS Top side of 1
3 Hard mask
5 Trench
10 Insulation collar
20 Conductive filling
30 Capacitor dielectric
50 Oxinitride liner layer
60 Silicon filling
70 Silicon liner layer
88 Silicon oxide filling
I,I′,I″ Implantation
70a,170a Implanted region
70b oxidized implanted region
80 Buried contact made of silicon
109,110 Silicon oxide filling
150 Silicon nitride liner layer
160 BPSG filling
170 Al₂O₃ liner layer

1. A fabrication method for a trench capacitor with an insulation collar in a substrate, which is electrically connected to the substrate on one side via a buried contact, comprising:
providing a trench in the substrate using a hard mask with a corresponding mask opening;
providing a capacitor dielectric in a lower and central trench regions, the insulation collar in the central and upper trench regions and an electrically conductive filling in the lower and central trench regions, the top side of the electrically conductive filling and the insulation collar being sunk into the trench relative to the top side of the substrate;
providing at least one liner layer in the trench;
filling the trench with a filling made of an auxiliary material, which filling is encapsulated by the at least one liner layer in the trench;
providing a mask on the filling for defining the structure of the buried contact, the mask having no projections into the trench;
removing a part of the filling using the mask;
removing an underlying part of the at least one liner layer for uncovering a corresponding part of the insulation collar;
removing a part of the insulation collar; and
forming the buried contact between the conductive filling and the semiconductor substrate.

2. A fabrication method for a trench capacitor with an insulation collar in a substrate, which is electrically connected to the substrate on one side via a buried contact, comprising:
providing a trench in the substrate using a hard mask with a corresponding mask opening;
providing a capacitor dielectric in lower and central trench regions, the insulation collar in the central and upper trench regions and an electrically conductive filling in the lower and central trench regions, the insulation collar being sunk relative to a top side of the electrically conductive filling and being replaced by a buried contact that is connected on all sides;
providing at least one liner layer in the trench;
filling the trench with a filling made of an auxiliary material, which filling is encapsulated by the at least one liner layer in the trench;
providing a mask on the filling for defining the structure of the buried contact, the mask having no projections into the trench;
removing a part of the filling using the mask;
removing an underlying part of the at least one liner layer for uncovering a corresponding part of the top side of the electrically conductive filling and the buried contact that is connected on all sides;
removing a part of the electrically conductive filling and the buried contact that is connected on all sides; and
providing an insulating filling between the conductive filling and the semiconductor substrate as replacement for the removed part of the electrically conductive filling and the buried contact that is connected on all sides.

3. The method according to claim 1, wherein providing the mask on the filling comprises:
sinking the filling into the trench;
providing a further liner layer in the trench;
carrying out at least one oblique, optionally rotated implantation into the liner layer for defining the mask; and
selectively etching the further liner layer for removing the non-implanted or implanted region.

4. The method according to claim 3, wherein the further liner layer is a silicon liner layer and, after the removal of the implanted or non-implanted region by the selective etching, an oxidation of the remaining region of the silicon liner layer is carried out, the oxidized region that has not been selectively etched forming the mask.

5. The method according to claim 3, wherein the further liner layer is an Al₂O₃ liner layer and, after the removal of the implanted or non-implanted region by the selective etching, the remaining region forms the mask.

6. The method according to claim 1, wherein the auxiliary material of the filling is silicon or borophosphosilicate glass.

7. The method according to a claim 4, wherein providing the further liner layer in the trench comprises:
depositing the silicon liner layer over the hard mask and the sunk filling;
providing a silicon oxide filling that is planar with a top side of the silicon liner layer;
pulling back the silicon liner layer to below the top side of the hard mask; and
removing the silicon oxide filling.

8. The method according to a claim 4, wherein the mask is removed after removal of a part of the filling using the mask by carrying out a further implantation and afterward a further selective etching.
